(19) United States
(12) Patent Application Publication
(10) Pub. No.: US 2025/0218750 A1
(43) Pub. Date: Jul. 3, 2025

(54) APPARATUS AND METHOD FOR MEASURING PLASMA DENSITY

(71) Applicant: SEMES CO., LTD., Cheonan-si (KR)

(72) Inventors: Sung Hyun YOON, Cheonan-si (KR); Chan Yong AN, Cheonan-si (KR); Ja Myung GU, Cheonan-si (KR); Gi Seong YUN, Pyeongtaek-si (KR)

(21) Appl. No.: 18/906,199

(22) Filed: Oct. 4, 2024

(30) Foreign Application Priority Data
Dec. 29, 2023 (KR) 10-2023-0195978

(51) Int. Cl. H01J 37/32

(52) U.S. Cl. CPC H01J 37/32917; H01J 2237/24495; H01J 2237/24585

(57) ABSTRACT

The present disclosure relates to an apparatus for measuring plasma density and a method for measuring plasma density, the apparatus including: a chamber having a processing space therein; a plasma generating unit for generating plasma in the processing space; an upper plate disposed in an upper portion of the chamber and having a plurality of through-holes; and a measuring unit including a measuring cable penetrating the upper plate, and measuring plasma density in each position of the processing space based on the measured transmission coefficient using the measuring cable.

### CROSS-REFERENCE TO RELATED APPLICATION(S)

This application claims benefit of priority to Korean Patent Application No. 10-2023-0195978 filed on Dec. 29, 2023 in the Korean Intellectual Property Office, the disclosure of which is incorporated herein by reference in its entirety.

### BACKGROUND

### 1. Field

The present disclosure relates to an apparatus for measuring plasma density and a method for measuring plasma density.

### 2. Description of Related Art

Plasma is a gaseous state separated into ions, radicals, electrons, and the like, at high temperature. Plasma is generated by very high temperatures, strong electric fields, or high-frequency electromagnetic fields (RF electromagnetic fields).

A process for manufacturing a semiconductor device may include a process of etching a surface of a substrate to form a desired pattern on the substrate. The etching process may be performed by ions or radicals included in the plasma colliding with, or reacting with a thin film formed on the substrate.

To control the processing process of the substrate performed using plasma, it is necessary to detect the distribution information of plasma within the chamber. As a method for observing plasma within the chamber, there are provided a method of indirectly observing plasma through an optical spectrum emitted from plasma using an Optical Emission Spectroscopy (OES) sensor, and a method of directly inserting a probe into a space in which plasma is formed.

The method of indirectly observing plasma through the optical spectrum may have a problem in which the accuracy of an observation value is reduced, and the method of indirectly inserting a probe may have a problem in which interference with plasma occurs.

### SUMMARY

An aspect of the present disclosure is to provide an apparatus for measuring plasma density and a method for measuring plasma density that can monitor plasma density information in each position of a processing space.

An aspect of the present disclosure is to provide an apparatus for measuring plasma density and a method for measuring plasma that can measure a transmission coefficient using a measuring cable penetrating an upper plate and having a planar-type probe, not protruding into the processing space, and derive a plasma density value based on the transmission coefficient.

An aspect of the present disclosure is to provide an apparatus for measuring plasma density and a method for measuring plasma that can observe plasma density information in each position of a processing space through switching.

According to an aspect of the present disclosure, an apparatus for measuring plasma density and a method for measuring plasma density are provided.

According to an aspect of the present disclosure, provided is an apparatus for measuring plasma density, the apparatus including: a chamber having a processing space therein; a plasma generating unit for generating plasma in the processing space; an upper plate disposed in an upper portion of the chamber and having a plurality of through-holes; and a measuring unit including a measuring cable penetrating the upper plate, and measuring plasma density information in each position of the processing space based on a transmission coefficient measured using the measuring cable.

According to an aspect of the present disclosure, provided is a method for measuring plasma density, the method including: generating plasma in a processing space inside a chamber; measuring a transmission coefficient using a measuring cable penetrating an upper plate disposed in an upper portion of the chamber; and measuring plasma density in each position of the processing space based on the transmission coefficient.

According to an aspect of the present disclosure, provided is an apparatus for measuring plasma density, the apparatus including: a chamber having a processing space therein; an upper plate disposed in an upper portion of the chamber and having a plurality of through-holes; a plasma generating unit supplying a processing gas to the processing space, and generating plasma from the processing gas in an upper portion of the upper plate; a substrate support unit disposed in a lower portion of the upper plate and supporting a substrate; a signal generator generating a measurement signal; a signal analyzer analyzing a collection signal; and a measuring unit including a measuring cable penetrating the upper plate, and measuring the plasma density in each position of the processing space based on a transmission coefficient measured using the measuring cable, wherein the measuring cable includes a signal application cable connected to the signal generator, and applying the measurement signal generated from the signal generator to a lower portion of the upper plate, and a signal collection cable connected to the signal analyzer, and transmitting the collection signal collected from the lower portion of the upper plate to the signal analyzer.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 illustrates an apparatus for measuring plasma density according to an embodiment of the present disclosure;

FIG. 2 illustrates a partial configuration of an apparatus for measuring plasma density according to an embodiment of the present disclosure;

FIG. 3 illustrates a partial configuration of an apparatus for measuring plasma density according to an embodiment of the present disclosure;

FIG. 4 is a graph exemplarily illustrating a transmission coefficient measured according to a method for measuring plasma density according to an embodiment of the present disclosure; and

FIG. 5 is a flow chart of a method for measuring plasma density according to an embodiment of the present disclosure.

### DETAILED DESCRIPTION

Hereinafter, embodiments will be described in detail so that those skilled in the art may easily practice the present disclosure with reference to the accompanying drawings. However, in describing an embodiment in detail, if it is determined that a detailed description of a related known function or configuration may unnecessarily obscure the gist of the present disclosure, the detailed description will be omitted. In addition, the same reference numerals are used throughout the drawings for parts having similar functions and actions. In addition, in the present specification, terms such as ‘on,’ ‘upper portion,’ ‘upper surface,’ ‘below,’ ‘lower portion,’ ‘lower surface,’ ‘side’ and the like are based on the drawings, and may be changed depending on the direction in which components are actually disposed.

In addition, throughout the specification, when a part is said to be ‘connected’ to another part, it is not only ‘directly connected,’ but also ‘indirectly connected’ with other components therebetween. Further, ‘including’ a certain component means that other components may be further included, rather than excluding other components unless otherwise stated.

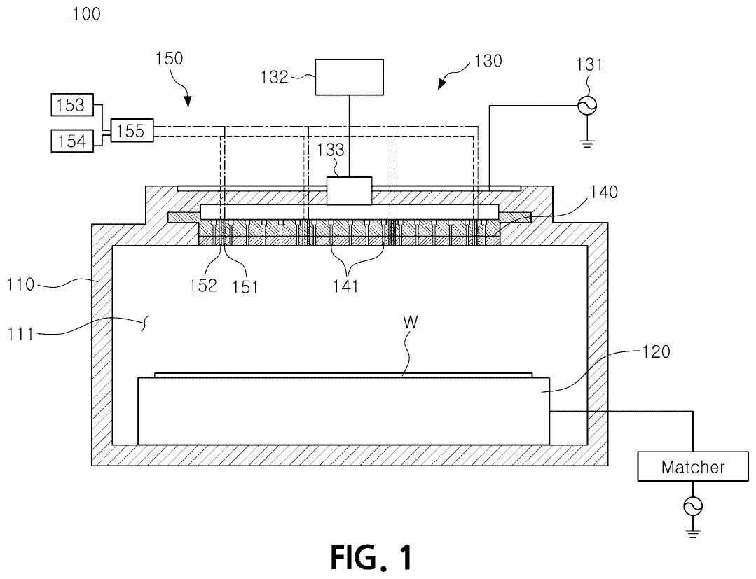

FIG. 1 illustrates an apparatus for measuring plasma density according to an embodiment of the present disclosure. Referring to FIG. 1, an apparatus for measuring plasma density 100 may include a chamber 110, a substrate support unit 120, a plasma generating unit 130, an upper plate 140, and a measuring unit 150.

The apparatus for measuring plasma density 100 may comprise a portion or all of an apparatus for processing a substrate performing processing on a substrate W using plasma. The processing on the substrate W may include, for example, an etching process.

The chamber may have a processing space 111 formed therein. The processing space 111 may be an environment that can be controlled with an appropriate temperature and pressure to perform processing on the substrate W.

A substrate support unit 120 may be disposed inside the chamber 110. The substrate support unit 120 may include a substrate support surface supporting a substrate W and adsorbing and fixing the substrate W.

The substrate support unit 120 may receive a DC voltage and adsorb the substrate W by electrostatic force. In addition, the substrate support unit 120 may be controlled to have a preset temperature in order to control the processing on the substrate W.

The plasma generating unit 130 may generate plasma in the processing space 111. The plasma generating unit 130 may include a voltage application unit 131, a gas supply unit 132, and a gas inlet unit 133.

The voltage application unit 131 can generate a high-frequency voltage for generating plasma. The high-frequency voltage generated by the voltage application unit 131 may be applied to an electrode disposed in an upper portion of the chamber 110.

The gas supply unit 132 can supply a processing gas to the processing space 111 through the gas inlet unit 133. When a high-frequency voltage is applied by the voltage application unit 131, plasma can be generated from the processing gas supplied to the processing space 111.

The upper plate 140 may be disposed in an upper portion of the substrate support unit 120 above the chamber 110. The upper plate 140 may have a plurality of through-holes 141 formed to penetrate the upper plate 140 in a vertical direction.

The upper plate 140 may include a shower head providing plasma radicals or one or more gases to a substrate W disposed therebelow through the plurality of through-holes 141.

The measuring unit 150 can measure plasma density in each position of the processing space 111. The measuring unit 150 may include a measuring cable disposed inside the upper plate 140.

The measuring unit 150 may include a plurality of measuring cables. The plurality of measuring cables may be disposed in different positions of the upper plate 140. The measuring cable can pass through the upper plate 140. The measuring unit 150 can measure the transmission coefficient using the measuring cable.

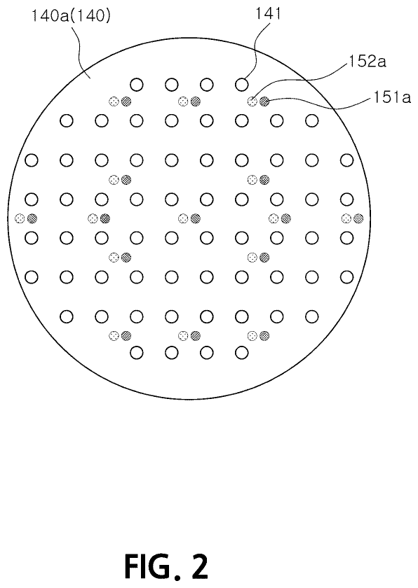

FIG. 2 illustrates a lower surface 140a of the upper plate 140 in the apparatus for measuring plasma density 100 according to an embodiment of the present disclosure.

The measuring cable may include a signal application cable 151 and a collection cable 152. A signal application tip 151a may be formed below the signal application cable 151, and a signal collection tip 152a may be formed below the signal collection cable 152.

In the upper plate 140, the signal application cable 151 and the signal collection cable 152 may be disposed adjacent to each other. Therefore, as shown in FIG. 2, the signal application tip 151a and the signal collection tip 152a may be disposed adjacent to each other on the lower surface 140a of the upper plate 140.

The measuring unit 150 may further include a signal generator 153 for generating a measurement signal and a signal analyzer 154 for analyzing a collection signal.

The measurement signal generated from the signal generator 153 may be applied to a lower portion of the upper plate 140 through the signal application cable 151.

In addition, the signal collection cable 152 may transmit the collection signal collected from the lower portion of the upper plate 140 to the signal analyzer 154. The collection signal collected through the signal connection cable 152 may be a signal obtained after a signal applied by the signal application cable 151 passes through the plasma of the processing space 111.

A lower cross-section of the signal application tip 151a may be positioned on the same plane as a lower surface 140a of the upper plate 140, and a lower cross-section pf the signal collection tip 152a may be positioned on the same plane as the lower surface 140a of the upper plate 140.

In the present disclosure, by using a planar-type probe as a means for measuring plasma density of a processing space 111, a space occupied by the probe in the apparatus may be optimized, and the impact on an environment or process inside the chamber 110 may be minimized.

A measurement signal of a variable frequency may be applied to plasma in the processing space 111 through the signal input cable 151.

The measuring unit 150 may include a plurality of measuring cables disposed in different positions of the upper plate 140. The measuring unit 150 may further include a switching member 155 for switching between the plurality measuring cables.

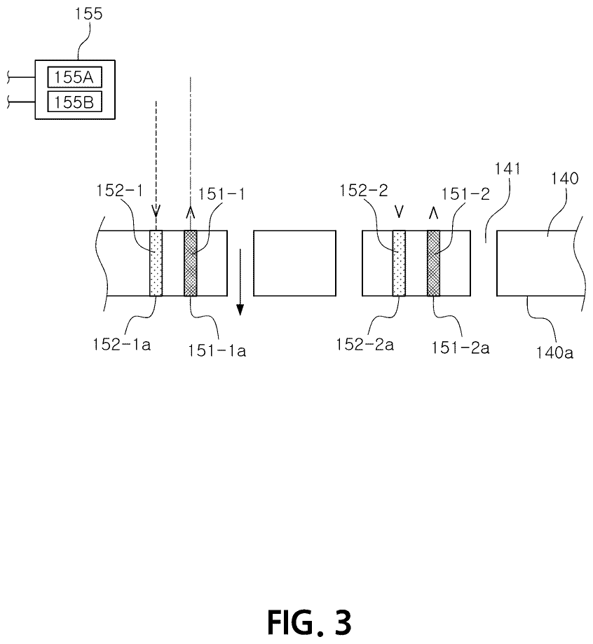

FIG. 3 illustrates a portion of a side cross-section of the upper plate 140. For example, the plurality of measuring cables may include a first measuring cable and a second measuring cable.

The first measuring cable may include a first signal application cable 151-1 and a first signal collection cable 152-1. In addition, the second measuring cable may include a second signal application cable 151-2 and a second signal collection cable 152-2.

As illustrated in FIG. 3, the first signal application cable 151-1, the first signal collection cable 152-1, the second signal application cable 151-2, and the second signal collection cable 152-2 may be disposed to penetrate the upper plate 140.

A first signal application tip 151-1a may be formed in a lower portion of the first signal application cable 151-1, and a first signal collection tip 152-1a may be formed in a lower portion of the first signal collection cable 152-1.

A lower cross-section of the first signal application tip 151-la may be positioned on the same plane as the lower surface 140a of the upper plate 140, and a lower cross-section of the first signal collection tip 152-1a may be positioned on the same plane as the lower surface 140a of the upper plate 140.

A second signal application tip 151-2a may be formed in a lower portion of the second signal application cable 151-2, and a second signal collection tip 152-2a may be formed in a lower portion of the second signal collection cable 152-2.

A lower cross-section of the second signal application tip 151-2a may be positioned on the same plane as the lower surface 140a of the upper plate 140, and a lower cross-section of the second signal collection tip 152-2a may be positioned on the same plane as the lower surface 140a of the upper plate 140.

In addition, the switching member 155 may include an application switching member 155A and a collection switching member 155B.

The application switching member 155A may connect the signal generator 153 to any one of the first signal application cable 151-1 or the second signal application cable 151-2.

The collection switching member 155B may connect the signal analyzer 154 to any one of the first signal collection cable 152-1 or the second signal collection cable 152-2.

When the signal generator 153 is connected to the first signal application cable 151-1 by the application switching member 155A, the measuring unit 150 may connect the signal analyzer 154 to the first signal connection cable 152-1 by the collection switching member 155B.

In addition, when the signal generator 153 is connected to the second signal application cable 151-2 by the application switching member 155A, the measuring unit 150 may connect the signal analyzer 154 to the second signal connection cable 152-2 by the collection switching member 155B.

That is, the measuring unit 150 may control the application switching member 155A and the collection switching member 155B, to operate the signal application cable and the signal collection cable, disposed adjacent to each other on the upper plate 140 and correspond to each other.

The measuring unit 150 may sweep a frequency of the measurement signal. Specifically, the signal generator 153 may vary the frequency of the measurement signal in a direction of gradually increasing or gradually decreasing.

The signal analyzer 154 may receive a collection signal obtained after a measurement signal of variable frequency passes through the plasma of the processing space 111 through a signal collection cable 152.

The signal analyzer 154 may derive a transmission coefficient based on the wave of the collection signal, and derive a resonant frequency of the plasma based on the transmission coefficient.

The transmission coefficient according to the frequency of the collection signal can be derived by Equation 1.

$${S}_{21} = 10 log \frac{50}{50 + {Z}_{total}} [ dB ] \qquad [ Equation 1 ]$$

In addition, the resonant frequency of the plasma may be derived at the point at which Zₜₒₜₐₗ is maximum, as shown in Equation 2.

$${Z}_{total} = \frac{2}{j ω {C}_{s}} + \frac{1}{j ω {C}_{0} + \frac{1}{{R}_{p} + j ω {L}_{p}}} \qquad [ Equation 2 ]$$

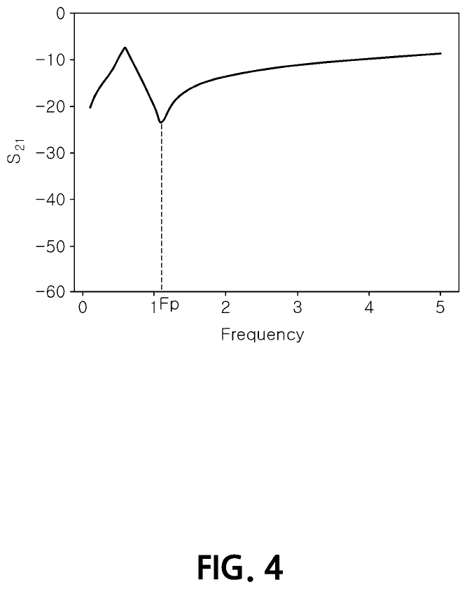

FIG. 4 is a graph exemplarily illustrating a transmission coefficient measured according to a method for measuring plasma density according to an embodiment of the present disclosure. FIG. 4 illustrates a graph of a transmission coefficient (S21) according to a frequency, illustrating electromagnetic wave transmission characteristics of plasma.

Based on a value of the transmission coefficient (S₂₁) shown in the graph of FIG. 4, a resonant frequency (Fₚ) of plasma may be derived at a point at which Zₜₒₜₐₗ is maximum.

The resonant frequency (Fₚ) of the plasma may quantitatively represent plasma density. The signal analyzer 154 may derive the plasma density based on the resonant frequency of the plasma. For example, when the resonant frequency of the plasma is Fₚ, the plasma density Dₚ may be derived through Equation 3.

$${D}_{p} = 1.24 * {F}_{p} ( GHz ) ⋀ 2 * {10}^{10} [ 1 / {cm}^{\text{?}} ] \qquad [ Equation 3 ]$$

$$\text{?} \text{indicates text missing or illegible when filed}$$

In the present disclosure, a transmission coefficient may be measured using a plurality of cables disposed in different positions of the upper plate 140, and therefrom, plasma density information in each position of the processing space 111 may be derived, and it is possible to obtain information on a change in plasma density gradient over time may be obtained through repeated measurements.

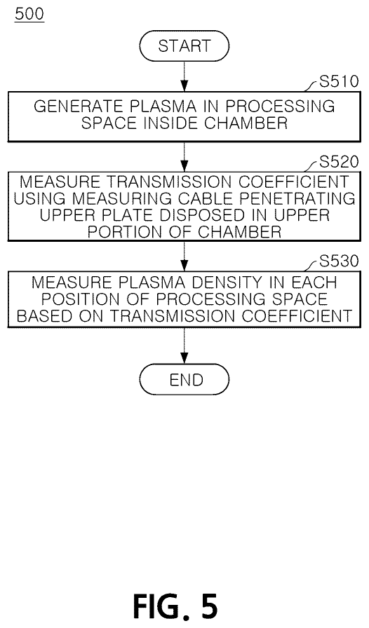

FIG. 5 is a flow chart of a method for measuring plasma density according to an embodiment of the present disclosure. A method for measuring plasma density 500 may be performed in whole or in part by the apparatus for measuring plasma density 100 described through FIGS. 1 to 4.

Referring to FIG. 5, the method for measuring plasma density 500 may include generating plasma in a processing space inside a chamber (S510), measuring a transmission coefficient using a measuring cable penetrating an upper plate disposed in an upper portion of the chamber (S520), and measuring plasma density in each position of the processing space based on the transmission coefficient (S530).

In the measuring the transmission coefficient (S520), the measuring cable may include a signal application cable and a signal collection cable penetrating an upper plate. The signal application cable and the signal collection cable may be disposed adjacent to each other on the upper plate.

In addition, a signal application tip may be formed in a lower portion of the signal application cable, and a signal collection tip may be formed in a lower portion of the signal collection cable. A lower cross-section of the signal application tip may be positioned on the same plane as a lower surface of the upper plate, and a lower cross-section of the signal collection tip may be positioned on the same plate as the lower surface of the upper plate.

In the present disclosure, by measuring plasma density using a planar-type probe not protruding into the processing space within the chamber, a space occupied by the probe in the apparatus may be minimized, and the impact on an environment and process within the chamber may be minimized.

The measuring a transmission coefficient (S520) may include applying a signal to a lower portion of the upper plate through a signal application cable and collecting a signal from the lower portion of the upper plate through a signal collection cable.

The applying a signal may include generating a signal by a signal generator connected to the signal application cable and inputting a signal to the signal application cable. The signal generator may vary a frequency of the signal in a direction of gradually increasing or gradually decreasing the frequency of the signal.

The collecting a signal may include detecting a signal with a signal collection cable and transmitting a signal detected by a signal analyzer connected to the signal collection cable.

The measuring a transmission coefficient (S520) may derive a transmission coefficient based on a wave of the signal transmitted to the signal analyzer.

The measuring plasma density in each position of the processing space (S530) may include deriving a resonant frequency of the plasma based on the transmission coefficient and deriving plasma density based on the resonant frequency of the plasma.

The measuring cable for measuring a transmission coefficient may include a plurality of measuring cables positioned in different positions of the upper plate.

The method for measuring plasma density (500) may further include switching between a plurality of measuring cables.

The switching between the plurality of measuring cables may include switching an application signal and switching a collection signal.

For example, the plurality of measuring cables may include a first measuring cable and a second measuring cable.

The first measuring cable may include a first signal application cable and a first signal collection cable disposed adjacent to each other, and the second measuring cable may include a second signal application cable and a second signal collection cable disposed adjacent to each other.

In the switching an application signal, the signal generator may be connected to the first signal application cable, and in the switching a collection signal, the signal analyzer may be connected to the first signal collection cable.

In addition, in the switching an application signal, the signal generator may be connected to the second signal application cable, and in the switching a collection signal, the signal analyzer may be connected to the second signal collection cable.

That is, in the method for measuring plasma density, the signal application cable and the signal collection cable, disposed adjacent to each other and corresponding to each other, may be switched to operate.

In addition, in describing the present disclosure, ‘-part’ or ‘unit’ may be implemented in various manners, for example, by a processor, program instructions executed by the processor, software modules, microcodes, computer program products, logic circuits, application-specific integrated circuits, firmware, or the like.

The contents of the method disclosed in the embodiments of the present application may be directly implemented by a hardware processor, or may be implemented and completed by a combination of hardware and software modules among processors. The software modules may be stored in storage media of the related art such as random access memory, flash memory, read only memory, programmable read only memory or electrically erasable programmable memory, registers, or the like. The storage medium is located in a memory, and the processor reads the information stored in the memory and combines with the hardware to complete the content of the above method. To avoid duplication, detailed descriptions are omitted herein.

In the process of implementation, each content of the above-described method may be completed by a logic integrated circuit of hardware in a processor or instructions in the form of software.

That is, those skilled in the art know that it may be implemented by electronic hardware or a combination of computer software and electronic hardware by combining each exemplary unit and algorithm operation described in the embodiments disclosed in this specification. Whether these functions are performed by hardware or software is determined by the specific application of the technical solution and the design constraints. Those skilled in the art may implement the described functionality using different methods for respective particular applications, but such implementations should not be considered outside the scope of the present application.

In the several embodiments provided in this application, it should be understood that the disclosed devices and methods may be implemented in other manners. For example, the device embodiments described above are merely illustrative, and for example, the division of the unit is only a logical function division, and in actual implementation, other division methods may be provided. For example, a plurality of units or the assembly may be coupled or integrated into one other system, or some features may be ignored or not performed. On the other hand, the couplings or direct couplings or mutual communication connections illustrated or discussed may be indirect couplings or communication connections through some interface, device or unit, and may be electrical, mechanical or other types.

A unit described above as a separate component may be physically separate, and a component indicated as a unit may or may not be a physical unit, for example, may be located in one place or may be distributed over a plurality of network units. According to actual needs, some or all thereof may be selected to realize the purpose of the solution in this embodiment.

That is, each functional unit in each embodiment of the present application may be integrated into one processing unit, each unit may be present alone, or two or two or more units may be integrated into one unit.

If the function is implemented in the form of a software functional unit and sold or used as an independent product, the function may be stored in a single computer readable storage medium. Based on this understanding, the technical solution of this application essentially or contributed to the related art, or a portion of the technical solution may be implemented in the form of a software product, and the computer software product is stored in a single storage medium. Thus, one computer device (which may be a personal computer, server, network device, or the like), including some instructions, may perform all or a portion of the operations of the method described in each embodiment of the present application. Examples of the above-described storage medium include various media capable of storing program codes, such as a USB memory, a mobile hard disk, a read-only memory (ROM), a random access memory (RAM), a magnetic disk, or a CD-ROM.

As set forth above, according to the present disclosure, an apparatus for measuring plasma density and a method for measuring plasma density that can monitor plasma density information in each position of a processing space may be provided.

In an embodiment of the present disclosure, it is possible to provide an apparatus for measuring plasma density and a method for measuring plasma density that can measure a transmission coefficient using a measuring cable penetrating an upper plate and having a planar-type probe, not protruding into the processing space, and derive a plasma density value based on the transmission coefficient.

In an embodiment of the present disclosure, an apparatus for measuring plasma density and a method for measuring plasma density that can observe plasma density information in each position of the processing space through switching may be provided.

While example embodiments have been illustrated and described above, it will be apparent to those skilled in the art that modifications and variations could be made without departing from the scope of the present disclosure as defined by the appended claims.

What is claimed is:

1. An apparatus for measuring plasma density, comprising:
a chamber having a processing space therein;
a plasma generating unit for generating plasma in the processing space;
an upper plate disposed in an upper portion of the chamber and having a plurality of through-holes; and
a measuring unit including a measuring cable penetrating the upper plate, and measuring plasma density in each position of the processing space based on the measured transmission coefficient using the measuring cable.

2. The apparatus for measuring plasma density of claim 1, wherein the measuring cable includes a signal application cable and a signal collection cable disposed adjacent to each other on the upper plate.

3. The apparatus for measuring plasma density of claim 2, wherein the measuring unit further includes a signal generator for generating a measurement signal and a signal analyzer for analyzing a collection signal,
the signal application cable applies the measurement signal generated from the signal generator to a lower portion of the upper plate, and
the signal collection cable transmits the collection signal collected from the lower portion of the upper plate to the signal analyzer.

4. The apparatus for measuring plasma density of claim 3, wherein the signal application cable includes a signal application tip formed therebelow,
the signal collection cable includes a signal collection tip formed therebelow,
a lower cross-section of the signal application tip is located on the same plane as a lower surface of the upper plate, and
a lower cross-section of the signal collection tip is located on the same plane as the lower surface of the upper plate.

5. The apparatus for measuring plasma density of claim 4, wherein the signal generator varies a frequency of the measurement signal in a direction gradually increasing or gradually decreasing, and
the signal analyzer derives a transmission coefficient based on a wave of the collection signal, derives a resonant frequency of the plasma based on the transmission coefficient, and derives the plasma density based on the resonant frequency of the plasma.

6. The apparatus for measuring plasma density of claim 3, wherein the measuring cable includes a plurality of measuring cables disposed in different positions of the upper plate, and
the measuring unit further includes a switching member switching between the plurality of measuring cables.

7. The apparatus for measuring plasma density of claim 6, wherein the measuring unit changes a measurement position of the transmission coefficient using the switching member, and measures the plasma density in each position of the processing space.

8. The apparatus for measuring plasma density of claim 6, wherein the plurality of measuring cables include
a first measuring cable including a first signal application cable and a first signal collection cable; and
a second measuring cable including a second signal application cable and a second signal collection cable,
wherein the switching member includes
an application switching member connecting the signal generator to any one of the first signal application cable or the second signal application cable; and
a collection switching member connecting the signal analyzer to any one of the first signal collection cable or the second signal collection cable.

9. The apparatus for measuring plasma density of claim 8, wherein, when the signal generator is connected to the first signal application cable by the application switching member, the measuring unit connects the signal analyzer to the first signal collection cable by the collection switching member, and
when the signal generator is connected to the second signal application cable by the application switching member, the measuring unit connects the signal analyzer to the second signal collection cable by the collection switching member.

10. A method for measuring plasma density, comprising:
generating plasma in a processing space inside a chamber;
measuring a transmission coefficient using a measuring cable penetrating an upper plate disposed in an upper portion of the chamber; and
measuring plasma density in each position of the processing space based on the transmission coefficient.

11. The method for measuring plasma density of claim 10, wherein the measuring cable includes:
a signal application cable penetrating the upper plate; and
a signal collection cable penetrating the upper plate, and disposed adjacent to the signal application cable on the upper plate,
wherein the measuring the transmission coefficient includes:
applying a signal to a lower portion of the upper plate through the signal application cable; and
collecting the signal from the lower portion of the upper plate through the signal collection cable.

12. The method for measuring plasma density of claim 11, wherein the applying the signal includes
generating the signal by a signal generator connected to the signal application cable; and
inputting the signal to the signal application cable.

13. The method for measuring plasma density of claim 12, wherein the collecting the signal includes
detecting the signal with the signal collection cable; and
transmitting the detected signal to a signal analyzer connected to the signal collection cable.

14. The method for measuring plasma density of claim 13, wherein the signal application cable includes a signal application tip formed therebelow,
the signal collection cable includes a signal collection tip formed therebelow,
a lower cross-section of the signal application tip is located on the same plane as a lower surface of the upper plate, and
a lower cross-section of the signal collection tip is located on the same plane as the lower surface of the upper plate.

15. The method for measuring plasma density of claim 13, wherein the generating the signal includes
varying a frequency of the signal in a direction of gradually increasing or gradually decreasing,
wherein the measuring the transmission coefficient includes
deriving the transmission coefficient based on a wave of the signal transmitted to the signal analyzer.

16. The method for measuring plasma density of claim 15, wherein the measuring the plasma density includes
deriving a resonant frequency of the plasma based on the transmission coefficient; and
deriving the plasma density based on the resonant frequency of the plasma.

17. The method for measuring plasma density of claim 16, wherein the measuring cable includes a plurality of measuring cables disposed in different positions of the upper plate,
the method, further comprising:
switching between the plurality of measuring cables.

18. The method for measuring plasma density of claim 17, wherein the switching between the plurality of measuring cables includes:
switching an application signal; and
switching a collection signal.

19. The method for measuring plasma density of claim 18, wherein the plurality of measuring cables include:
a first signal application cable;
a first signal collection cable disposed adjacent to the first signal application cable;
a second signal application cable;
a second signal collection cable disposed adjacent to the second signal application cable,
wherein, when the signal generator is connected to the first signal application cable in the switching the application signal, the signal analyzer is connected to the first signal collection cable in the switching the collection signal, and
when the signal generator is connected to the second signal application cable in the switching the application signal, the signal analyzer is connected to the second signal collection cable in the switching the collection signal.

20. An apparatus for measuring plasma density, comprising:
a chamber having a processing space therein;
an upper plate disposed in an upper portion of the chamber and having a plurality of through-holes;
a plasma generating unit supplying a processing gas to the processing space, and generating plasma from the processing gas in an upper portion of the upper plate;
a substrate support unit disposed in a lower portion of the upper plate and supporting the substrate;
a measuring unit including a signal generator for generating a measurement signal, a signal analyzer for analyzing a collection signal, and a measuring cable penetrating the upper plate, and measuring the plasma density in each position of the processing space based on a transmission coefficient measured using the measuring cable,
wherein the measuring cable includes a signal application cable connected to the signal generator, and applying the measurement signal generated from the signal generator to a lower portion of the upper plate; and
a signal collection cable connected to the signal analyzer, and transmitting the collection signal collected from the lower portion of the upper plate to the signal analyzer.
